(19) United States
(12) Patent Application Publication
(10) Pub. No.: US 2014/0339706 A1
(43) Pub. Date: Nov. 20, 2014

(54) INTEGRATED CIRCUIT PACKAGE WITH AN INTERPOSER FORMED FROM A REUSABLE CARRIER SUBSTRATE

(71) Applicant: NVIDIA CORPORATION, Santa Clara, CA (US)

(72) Inventors: Abraham F. YEE, Cupertino, CA (US); John Y. CHEN, Cupertino, CA (US)

(73) Assignee: NVIDIA CORPORATION, Santa Clara, CA (US)

(21) Appl. No.: 13/897,061

(22) Filed: May 17, 2013

(51) Int. Cl. H01L 23/522; H01L 21/768

(52) U.S. Cl. CPC H01L 23/5226; H01L 21/76877
USPC 257/774; 438/125

(57) ABSTRACT

An integrated circuit package includes an interposer and an integrated circuit die. The interposer is formed from a layer of semiconductor material that is separated from a bulk portion of a semiconductor substrate, and the integrated circuit die is coupled to the interposer. Vias in the interposer can be formed in the thin layer of semiconductor material removed from the semiconductor substrate, and therefore can be scaled down significantly in size. Such reduced-size, through-interposer vias can be etched and filled much more cost-effectively and result in greatly reduced parasitic capacitance in the integrated circuit package.

### BACKGROUND OF THE INVENTION

1. Field of the Invention

Embodiments of the present invention relate generally to integrated circuit chip packaging and, more specifically, to an integrated circuit package with an interposer formed from a reusable carrier substrate.

2. Description of the Related Art

In the packaging of integrated circuit (IC) chips, a key technology is the use of through-silicon vias (TSVs). TSVs are conductive paths formed entirely through an IC chip or silicon interposer, and help enable 3D chip design, which is a packaging design in which multiple IC chips are stacked or placed tightly side by side. In 3D chip design, signals can be transferred directly between chips in a chip package without using exceedingly long interconnect traces or wire bonds, thereby avoiding latency and crosstalk issues in the chip package.

Typically, when TSVs are formed through a silicon interposer, openings are etched into a silicon interposer substrate and filled with a conductive material, such as electroplated copper. For example, openings that are on the order of 5-10 microns in diameter and 50 to 100 microns deep may be used to form TSVs in a silicon interposer in this way. The interposer substrate is then thinned via grinding, polishing, and etching of the interposer substrate on the surface opposite the TSVs, until the conductive material filling the TSVs is exposed. Thus, after thinning, the interposer substrate is typically 50 to 100 microns thick and the TSVs are formed completely through the remaining portion of the thinned silicon interposer substrate.

Etching openings in the silicon interposer substrate, depositing insulating dielectric and the conductive material in the openings, and thinning the silicon interposer substrate are all costly and time-consuming processes. In addition, the thinning process is difficult-to-control and generally, involves trial-and-error, visual inspection, thickness measurements, and the like to ensure adequate process control.

Furthermore, for 3D chips, mismatch between the thermal expansion of the silicon and the conductive material forming TSVs in the silicon, such as copper, can create significant stresses in the 3D chip at operational temperatures. TSVs are commonly used to provide conductive paths in a silicon interposer, and therefore are configured with a relatively large volume of conductive material. Consequently, the stresses caused by thermal expansion mismatch between the TSVs and the silicon are sizable and can alter the threshold values of transistors anywhere nearby, thereby changing the performance of the chip in somewhat unpredictable ways. Because of this, 3D chips generally include an exclusion zone free of transistors or other active devices surrounding each TSV. These exclusion zones reduce the effects of such stresses caused by the TSVs, but are are wasteful of valuable surface area and increase cost.

Accordingly, there is a need in the art for an IC package that has smaller and more easily manufactured TSVs.

### SUMMARY OF THE INVENTION

One embodiment of the present invention sets forth an integrated circuit package comprising an interposer and an integrated circuit die. The interposer is formed from a layer of semiconductor material that is separated from a bulk portion of a semiconductor substrate, and the integrated circuit die is coupled to the interposer.

One advantage of the above-described embodiment is that through-interposer vias in an integrated circuit package can be formed from a thin layer of semiconductor material removed from a reusable carrier substrate, and therefore can be scaled down significantly in size. Such reduced-size, through-interposer vias can be etched and filled much more cost-effectively and result in greatly reduced parasitic capacitance in the integrated circuit package. Moreover, because the interposer of the integrated circuit package can be formed from a layer of semiconductor material separated from a substrate rather than via a thinning process, the interposer can be advantageously fabricated without imprecise and difficult-to-control thinning operations.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an integrated circuit (IC) package, arranged according to one embodiment of the invention.

FIG. 2 sets forth a flowchart of method steps for forming an IC package, according to an embodiment of the invention.

FIGS. 3A-3J sequentially illustrate the results of the method steps of FIG. 2.

FIG. 4 illustrates a computing device in which one or more embodiments of the present invention can be implemented.

For clarity, identical reference numbers have been used, where applicable, to designate identical elements that are common between figures. It is contemplated that features of one embodiment may be incorporated in other embodiments without further recitation.

### DETAILED DESCRIPTION

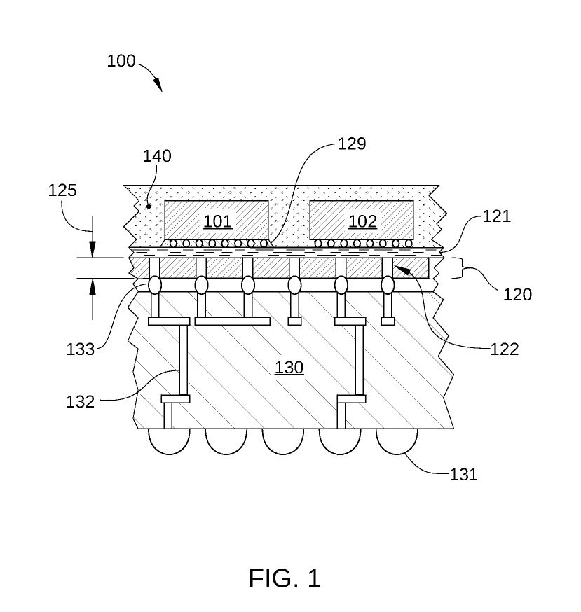

FIG. 1 is a schematic cross-sectional view of a IC package 100, arranged according to one embodiment of the invention. IC package 100 includes integrated circuit (IC) chips 101 and 102 coupled to an interposer 120, a packaging substrate 130, and an over-molding 140 formed over IC chips 101 and 102. IC package 100 is configured to electrically and mechanically connect IC chips 101, 102, and any other logic or memory ICs coupled to interposer 120 to a printed circuit board or other mounting substrate (not shown) external to IC package 100. In addition, IC package 100 protects IC chips 101 and 102 from ambient moisture and other contamination and minimizes mechanical shock and stress thereon.

Each of IC chips 101 and 102 may be a semiconductor die singulated from a separately processed semiconductor substrate, such as a central processing unit (CPU), a graphics processing unit (GPU), an application processor or other logic device, a memory chip, a global positioning system (GPS) chip, a radio frequency (RF) transceiver chip, a Wi-Fi chip, a system-on-chip, or any other semiconductor chip that is suitable for mounting on interposer 120. Thus, IC chips 101 and 102 may include any IC chips that may benefit from being assembled together in a single microelectronic package. Moreover, in FIG. 1, IC package 100 is shown with two IC chips, but in other embodiments IC package 100 may be configured with more or fewer IC chips. Thus, in some embodiments, IC package 100 may be configured as a system-on-chip and may include a heterogeneous assortment of IC chips.

In some embodiments, IC chip 101 may be logic chip, such as a CPU or GPU, and IC chip 102 may be a memory chip associated with IC chip 101. IC chips 101 and 102 may be coupled to interposer 120 using solder microbumps or any other technically feasible approach. In some embodiments, an underfill material 129 is used to protect the electrical connections between IC chips 101 and 102 and interposer 120, and in other embodiments, underfill material 129 is not used. In FIG. 1, IC chip 101 is depicted with underfill material 129 and IC chip 102 is depicted without underfill material 129.

IC chips 101 and 102 are electrically connected or otherwise coupled to each other with electrical interconnects formed in an interconnect layer 121 formed on interposer 120. The electrical interconnects of interconnect layer 121 are configured to electrically connect or otherwise couple IC chips 101 and 102 to each other and to through-interposer vias 122, which are formed in interposer 120 and are described below. These electrical interconnects may include ground, power, and signal connections to each of IC chips 101 and 102, and can be formed on interposer 120 using various wafer-level deposition, patterning, and etching processes, i.e., processes that are performed on a complete semiconductor wafer or other substrate. In this way, interconnect layer 121 can be formed simultaneously on a complete semiconductor substrate for a plurality of IC packages, and the semiconductor substrate is subsequently singulated into individual interposer elements, such as interposer 120, with interconnect layer 121 already formed thereon. IC package 100 may be formed using one such singulated interposer element.

In some embodiments, the electrical interconnects of interconnect layer 121 are formed using one or more deposition, patterning, and etching techniques used for forming the interconnects between the transistors of an integrated circuit formed on a semiconductor substrate. Thus, in such embodiments, interconnect layer 121 may include one or more levels of electrical interconnects, such as electroplated copper (Cu) or sputtered aluminum (Al), that are formed in alternating layers of a non-organic dielectric material, such as silicon dioxide. Interconnect layer 121 may further include a final passivation layer for protecting the top layer of electrical interconnects, and may be bumped with a conductive material, such as solder, for making electrical connections directly to IC chips 101 and 102. Interconnect layer 121 and through-interposer vias 122 effectively provide very short electrical connections between IC chips 101 and 102 and to an external packaging substrate.

Interposer 120 includes an intermediate semiconductor layer or structure that provides electrical connections between IC chips 101 and 102, any other IC chips mounted on interposer 120, and any technically feasible mounting substrate. For example, the mounting substrate may be a packaging substrate included in IC package 100, such as packaging substrate 130, or a printed circuit board external to IC package 100. Generally, interposer 120 may be electrically coupled to mounting substrate 130 with through-interposer vias 122 using any technically feasible electrical connection known in the art, including a ball-grid array (BGA), a pin-grid array (PGA), and the like.

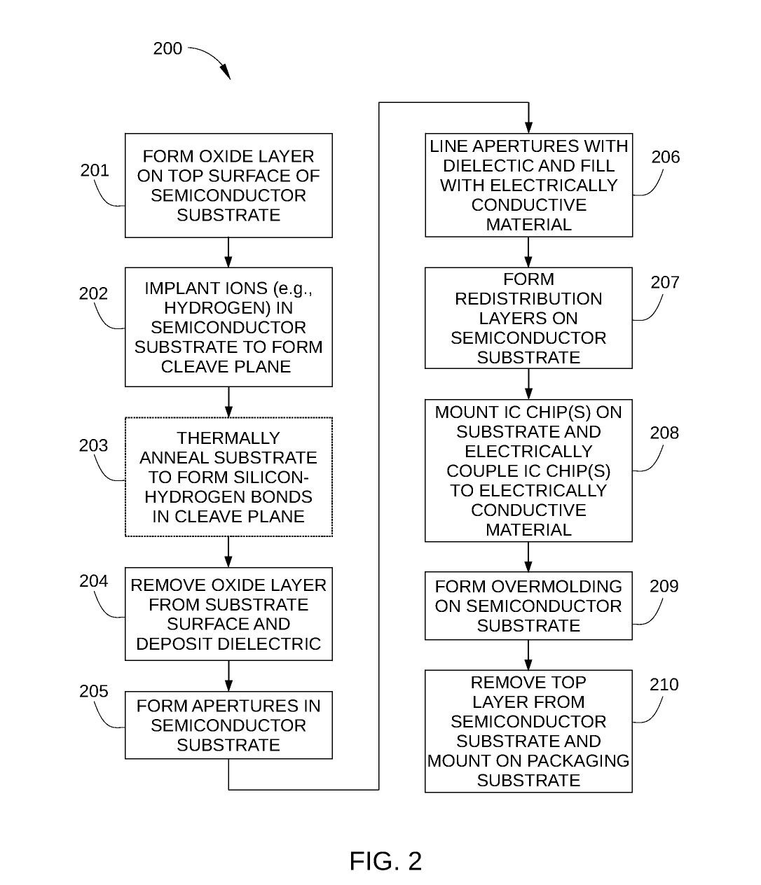

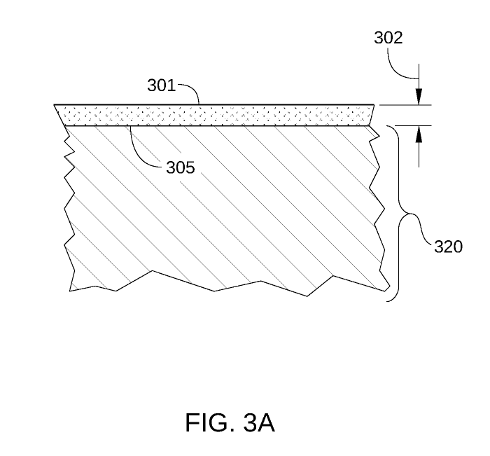

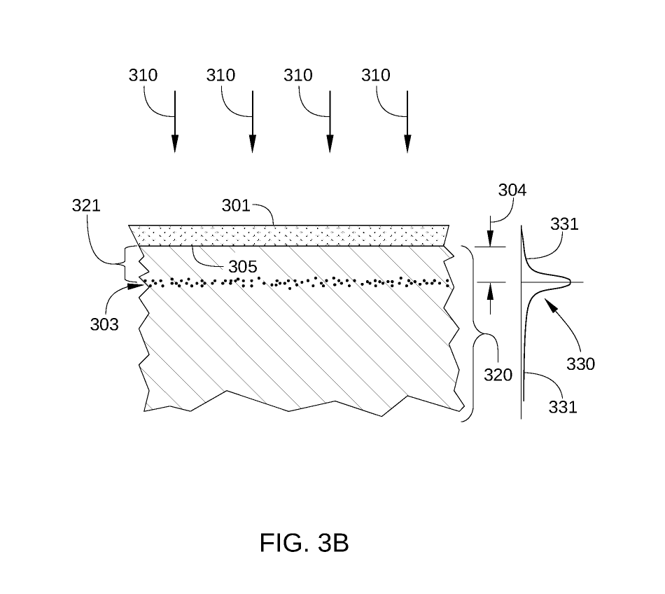

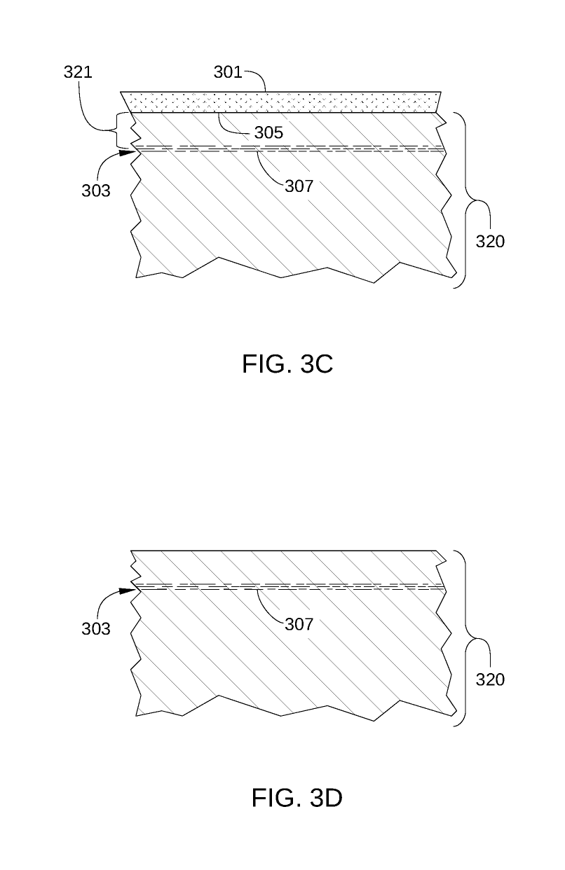

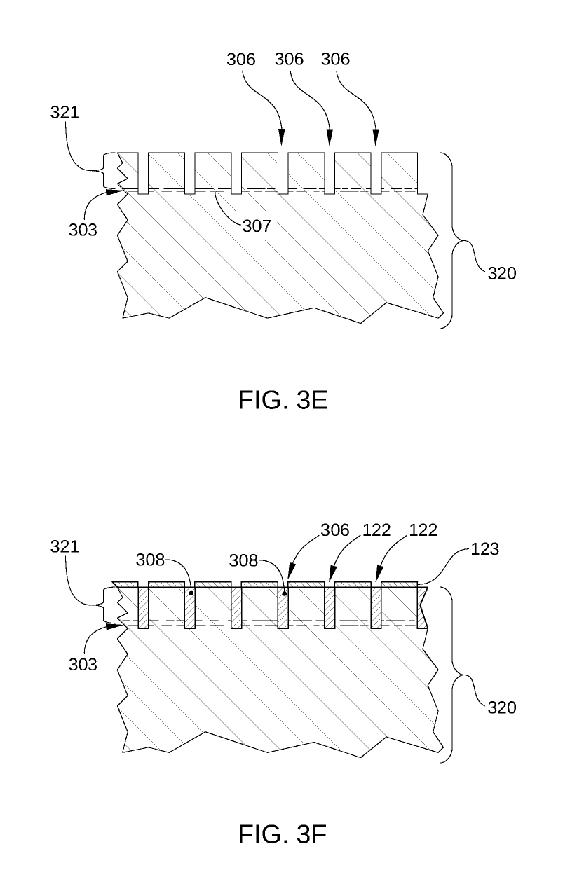

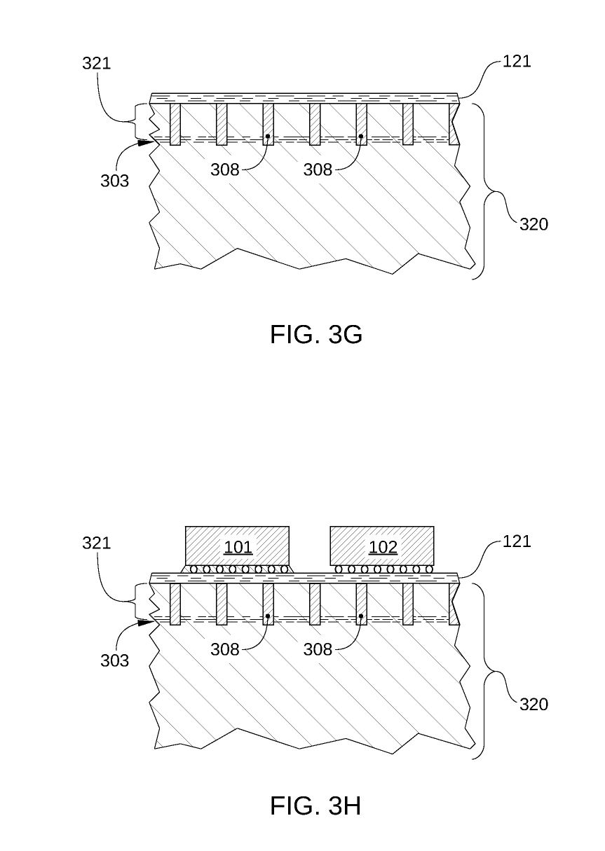

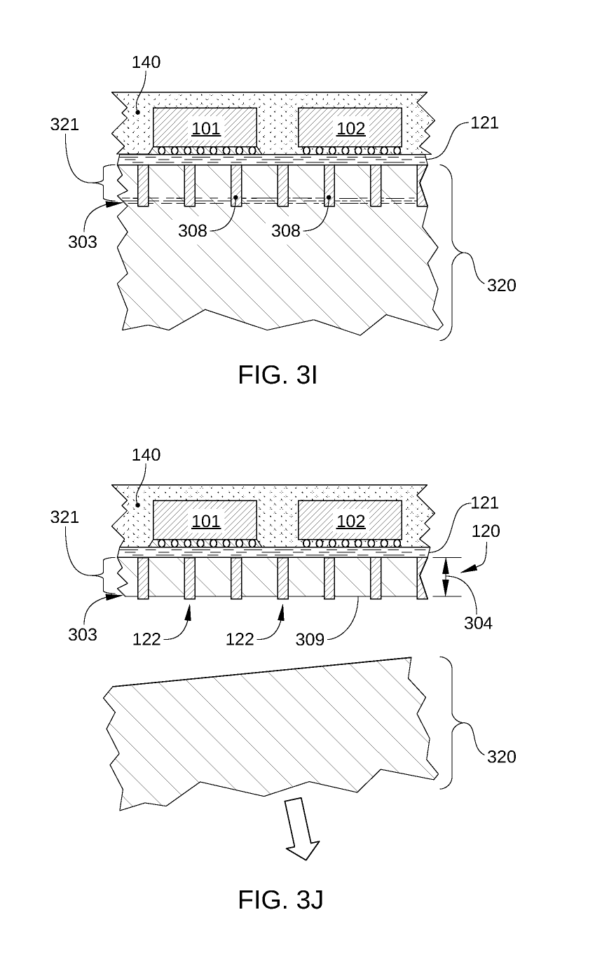

According to embodiments of the invention, interposer 120 is formed from a layer of semiconductor material that has been removed from a semiconductor substrate, such as an interposer carrier substrate. A process by which interposer 120 is formed from such a substrate is described below in conjunction with FIGS. 2 and 3A-3I. In some embodiments, interposer 120 is a monocrystalline silicon material removed from a silicon substrate. In other embodiments, interposer 120 may be a layer of any semiconductor material that can be removed from a semiconductor substrate, including germanium, gallium arsenide, silicon carbide, silicon-germanium alloys, and the like.

Interposer 120 is formed from a layer of semiconductor material that is separated from a substrate rather than by grinding down a semiconductor substrate to a targeted thickness via a thinning process. Consequently, interposer 120 can be much thinner than a silicon interposer formed by such a thinning process. This is because a cleave plane can be formed in a semiconductor substrate at a precisely controlled depth, the depth of the cleave plane defining the thickness of the layer of semiconductor material removed from the substrate and therefore the thickness of interposer 120. Thus, a thickness 125 of interposer 120 can be selected to be as thin as one micron, or one hundred nanometers, or even less. A process by which such a cleave plane can be formed in a semiconductor substrate at a precisely controlled depth is described below in conjunction with FIG. 2 and FIGS. 3A-3I.

In contrast, the formation of a silicon interposer by thinning a silicon substrate generally involves thinning the silicon substrate from a starting thickness of 750 to 800 microns down to a final thickness of about 50 to 100 microns, the thinning process ultimately exposing the through-silicon vias formed therein so that a conductive pathway is provided entirely through the silicon interposer. Thinning of a silicon substrate to less than 50 microns is problematic, since the substrate can be easily cracked during thinning and subsequent handling.

The difficulties associated with precisely thinning a silicon substrate down to a thickness of 100 microns or less are manifold. First, the thinning process is time-consuming and costly, typically involving multiple steps, including grinding, chemical-mechanical polishing, and silicon etching. Second, the thinning process is difficult to control, since the actual thickness of the silicon substrate is difficult to determine accurately while material is being removed therefrom. Third, handling silicon substrates thinned to 100 microns or less without cracking the substrate is challenging. Consequently, the silicon substrate being thinned usually undergoes the additional process steps of bonding to a silicon or glass carrier prior to thinning and debonding from the carrier after thinning, the carrier being used as a mechanism for handling the substrate. Furthermore, even when the silicon interposer is successfully thinned and de-bonded from the carrier without damage, the final thickness of the silicon interposer is generally much thicker than a layer of semiconductor material separated at a cleave plane from a semiconductor substrate. For example, a layer of semiconductor material removed from a semiconductor substrate at a cleave plane can have a thickness of one micron or less, which is one or more orders of magnitude thinner than a silicon substrate thinned down to 50 to 100 microns.

Through-interposer vias 122 are microvias formed through interposer 120, and may be configured to electrically couple IC chips 101 and 102 to a packaging substrate included in IC package 100 or to a printed circuit board external to IC package 100. Thus, rather than being 50 to 100 microns deep and having a diameter of 5-10 microns, which is typical for through-silicon vias formed in a silicon interposer formed by a thinning process, through-interposer vias 122 may be from 10 nm to 1 micron in diameter. Consequently, through-interposer vias 122 can be formed in interposer 120 using standard integrated circuit fabrication processes, including the patterning, etching, and filling processes used to form submicron interconnects in an integrated circuit. For example, in some embodiments, a typical process for forming a contact in an integrated circuit may be used to form through-interposer vias 122, which is a well-known, easily controlled, and reliable process.

Because thickness 125 can be 10 microns, 1 micron, or less, openings for through-interposer vias 122 can be formed quickly in interposer 120. Furthermore, because the aspect ratio of these openings can be selected to be relatively low, for example less than about 10:1, these openings can be filled quickly and reliably, for example, with aluminum, copper, tungsten (W), and the like. Moreover, the volume of each of through-interposer vias 122 is advantageously much less than the typical volume of through-silicon vias formed in a silicon interposer formed by a thinning process. For example, when interposer 120 has a thickness 125 of 100 nm, a through-interposer via 122 with a diameter of 100 nm has a volume that is approximately ten million time less than that of a through-silicon via having a diameter of 10 microns and a depth of 100 microns. Less conductive material in through-interposer vias 122 results in less parasitic capacitance during operation of IC chips 101 and 102. In addition, less volume of conductive material in through-interposer vias 122 results in less stresses in IC package 100 caused by thermal mismatch between the conductive material and interposer 120. Thus, in some embodiments, IC package 100 can be configured without exclusion zones for through-interposer vias 122. In other words, through-interposer vias 122 can be positioned very close to transistors and other semiconductor devices in IC package 100 without significantly affecting the performance of these semiconductor devices.

Packaging substrate 130 can be a rigid and thermally insulating substrate on which interposer 120 is mounted and provides IC package 100 with structural rigidity. Electrical connections 133 provide electrical connections between interposer 120 and packaging substrate 130, and may be any technically feasible electrical connection known in the art, for example C4 bumps formed on either substrate 120 or packaging substrate 130. In some embodiments, packaging substrate 130 is a laminate substrate and is composed of a stack of insulative layers or laminates that are built up on the top and bottom surfaces of a core layer. Packaging substrate 130 also provides an electrical interface for routing input and output signals and power between IC chips 101 and 102 and electrical connections 131. Electrical connections 131 provide electrical connections between IC package 100 and a printed circuit board or other mounting substrate external to IC package 100. Electrical connections 131 may be any technically feasible chip package electrical connection known in the art, including a ball-grid array (BGA), a pin-grid array (PGA), and the like. Packaging substrate also includes vias and interconnects 132 that route input and output signals and power between electrical connections 131 and electrical connections 133.

Overmolding 140 is formed on interposer 120 and encapsulates IC chips 101 and 102. Overmolding 140 may be an injection-molded component formed from a mold compound using an injection molding process. The material of overmolding 140 is selected to protect IC chips 101 and 102 from mechanical damage, exposure to moisture, and other ambient contamination. Overmolding 140 can also act as a stiffener to reduce warpage. In some embodiments, overmolding 140 can be configured so that IC chips 101 and 102 are not covered, in order to add a heatsink or heatspreader directly to IC chips 101 and/or 102 for effective heat removal. Alternatively, overmolding 140 can be planarized using a chemical-mechanical polishing process to remove molding material covering IC chips 101 and 102 and facilitate the addition of a heatsink or heatspreader directly to IC chips 101 and/or 102 for effective heat removal.

FIG. 2 sets forth a flowchart of method steps for forming an integrated circuit package, according to an embodiment of the invention. Although the method steps are described with respect to IC package 100 of FIG. 1, persons skilled in the art will understand that performing the method steps, in any order, to form other configurations of IC package is within the scope of the invention. FIGS. 3A-3I sequentially illustrate the results of steps 201-210 of FIG. 2.

The method 200 begins at step 201, where an oxide layer 301 is formed on a top surface 305 of a semiconductor substrate 320, such as a wafer formed from silicon, germanium, gallium arsenide, silicon carbide, a silicon-germanium alloy, etc. In some embodiments, semiconductor substrate 320 is formed as a monocrystalline semiconductor material. Oxide layer 301 may be formed by a deposition process, such as chemical vapor deposition, or by an oxidation process, in which semiconductor substrate 320 is exposed to an oxygen-containing gas or vapor at an elevated temperature and oxide layer 301 is formed from the material of semiconductor substrate 320. Oxide layer 301 can act as an ion implant mask and has a thickness 302 that is selected to prevent channeling of implantation ions in semiconductor substrate 320 during an ion implantation process, i.e., the traveling of implantation ions along grain boundaries of semiconductor substrate 320 to an unwanted depth. In some embodiments, thickness 302 is selected based on ion implantation parameters such as implantation energy, what ions 310 are implanted into semiconductor substrate 320, and the material of oxide layer 301.

In step 202, ions 310 are implanted into semiconductor substrate 320 through oxide layer 301 and top surface 305 to form a cleave plane 303 at a depth 304 in semiconductor substrate 320. Cleave plane 303 is a weakened interface layer in semiconductor substrate 320 that is substantially parallel to top surface 305 and can be used to separate a top layer 321 from semiconductor substrate 320 in a subsequent process step, e.g., step 210 of method 200. In embodiments in which semiconductor substrate 320 is a monocrystalline silicon wafer and top surface 305 corresponds to a principle crystallographic plane, e.g., a [1-0-0] plane, cleave plane 303 generally also corresponds to a principle crystallographic plane, thereby greatly facilitating cleaving of top layer 321 from semiconductor substrate 320. In some embodiments, ions 310 include hydrogen (H) ions, although in other embodiments other ions may be implanted in step 202 to form cleave plane 303.

Ions 310 are implanted into semiconductor substrate 320 at a dose selected to form a targeted concentration of ions 310 in cleave plane 303. For example, in embodiments in which hydrogen ions are implanted in cleave plane 303, the targeted concentration of ions 310 in cleave plane 303 may be from 10¹⁶ to 10²⁰ atoms/cm³. Such a concentration of hydrogen atoms can sufficiently weaken silicon-silicon bonds in semiconductor substrate 320 so that top layer 321 can be separated from semiconductor substrate 320 at cleave plane 303 in a controlled exfoliation process. Furthermore, the depth 304 at which ions 310 come to rest in semiconductor substrate 320 can be precisely selected with the ion implantation energy used in step 202. For example, hydrogen ions implanted at 50 to 150 KeV in step 202 may form cleave plane 303 at depth 304 of 0.5 to 1 micron below surface 305 of semiconductor substrate 320. By closely controlling the ion implantation energy of ions 310 in step 202, a tight distribution 330 of ions 310 results in a spike in concentration at a targeted depth, e.g., depth 304. As shown in FIG. 2B, the tails 331 of distribution 330 indicate very low concentration of ions 310 after step 202 throughout semiconductor substrate 320 except at depth 304. In some embodiments, the ion implantation of hydrogen ions form gaseous microbubbles along cleave plane 303.

In optional step 203, semiconductor substrate 320 is thermally annealed at a sufficient temperature and for a sufficient time to form silicon-hydrogen bonds in cleave plane 303 between hydrogen ions implanted in step 202 and silicon present in semiconductor substrate 320. Thus, the formation and linkage of regions of brittle silicon hydride is promoted in cleave plane 303. In this way, an intermittent or substantially contiguous layer of material 307 can be formed in cleave plane 303 that is mechanically weaker than the surrounding material of semiconductor substrate 320, as shown in FIG. 3C. For example, in some embodiments, semiconductor substrate 320 is thermally annealed at 400 to 600° C. in step 203.

In step 204, oxide layer 301 is removed from surface 305 using any technically feasible wet etch or dry etch process, as shown in FIG. 3D. The removal of oxide layer 301 may facilitate formation of apertures in semiconductor substrate 320 in step 205. In addition, an oxide layer or other dielectric layer may be deposited in step 204 that can be used as part of interconnect layer 121.

In step 205, apertures 306 are formed in semiconductor substrate 320, as shown in FIG. 3E. Apertures 306 are formed through cleave plane 303, so that through-interposer vias formed in apertures 306 are exposed when top layer 321 is separated from semiconductor substrate 320. Apertures 306 may be formed in step 205 using semiconductor patterning and etching techniques known in the art, such as reactive ion etching (RIE).

In step 206, apertures 306 are first lined with a layer of insulating dielectric 123, for example using a chemical vapor deposition process, and then filled with an electrically conductive material 308, such as electroplated copper, sputtered aluminum, tungsten deposited via chemical vapor deposition, and the like, as shown in FIG. 3F. In some embodiments, a seed layer, a barrier layer, or other conformal layer of conductive material may be deposited in apertures 306 prior to the process of filling apertures 306 with electrically conductive material 308. When apertures 306 are filled with electrically conductive material 308, through-interposer vias 122 are formed in top layer 321, although in step 206 through-interposer vias 122 do not yet form an electrically conductive path through top layer 321. After top layer 321 is removed from semiconductor substrate 320, as described below, through-interposer vias 122 provide such electrically conductive paths.

In step 207, insulating dielectric 123 is prepared for the mounting of IC chips 101 and 102 on semiconductor substrate 320, as shown in FIG. 3G. Specifically, one or more layers of electrical interconnects may be formed on semiconductor substrate 320, such as interconnect layer 121. Interconnect layer 121 may be formed using various wafer-level deposition, patterning, and etching processes known in the art, and may be configured to electrically couple IC chips 101 and 102 to each other and to electrically conductive material 308 in one or more of the apertures 306. In some embodiments, different layers of electrical interconnects in interconnect layer 121 are formed within non-organic dielectric films that are deposited on a surface of semiconductor substrate 320. For example, in some embodiments, insulating dielectric 123 is patterned, etched, and filled using conventional dual damascene metal deposition processes to form interconnect layer 121. A chemical-mechanical polishing process may then be used after such processes are used to form an interconnect layer in interconnect layer 121. The above processes may be repeated for additional interconnect layer in interconnect layer 121, the final interconnect layer including top layer pads for electrical connection to IC chips 101 and 102.

In step 208, IC chips 101 and 102 are mounted on semiconductor substrate 320 and electrically coupled to electrically conductive material 308 in one or more of the apertures 306 formed in semiconductor substrate 320, as shown in FIG. 3H. For example, IC ships 101 and 102 may be mechanically and electrically coupled to semiconductor substrate 320 with solder microbumps in a reflow process or other thermal process, such as thermal compression non-conductive paste (TCNCP).

In step 209, overmolding 140 is formed on semiconductor substrate 320 to encapsulate IC chips 101 and 102, as shown in FIG. 3I. Overmolding 140 may be an injection-molded component formed by injecting a suitable molten material, such as a molding compound, into a mold cavity or chase using techniques known in the art. The mold cavity may be formed with a removable mold assembly (not shown in FIG. 1 for clarity) coupled to interposer 120. After cooling and hardening of the molding compound and removal of the mold assembly, the injected molding compound forms overmolding 140 as shown in FIG. 1. In some embodiments, overmolding 140 for a plurality of IC packages can be formed simultaneously with a single mold assembly prior to singulation of IC package 100. The material of overmolding 140 is selected to protect IC chips 101 and 102 from mechanical damage, exposure to moisture, and other ambient contamination. In some embodiments, overmolding 140 can be planarized using a chemical-mechanical polishing process to remove molding material covering IC chips 101 and 102 and facilitate the addition of a heatsink or heatspreader directly to IC chips 101 and/or 102 for effective heat removal.

In step 210, top layer 321 is removed from semiconductor substrate 320, thereby forming interposer 120 and exposing through-interposer vias 122 on bottom surface 309 of interposer 120, as shown in FIG. 3J. Various methods may be used to separate top layer 321 from semiconductor substrate 320 in step 210. For example, in one embodiment, a room-temperature mechanical fracturing process may be used involving application of a pressurized air burst that initiates a separation fracture between top layer 321 and the remaining portion of semiconductor substrate 320, the separation fracture rapidly propagating through cleave plane 303. In another embodiment, a thermal process is used to separate top layer 321 from semiconductor substrate 320, in which heating of semiconductor substrate 320 to a sufficient temperature causes pressure in hydrogen microbubbles in cleave plane 303 to build to a magnitude that separates top layer 321 from semiconductor substrate 320. Moreover, use of any other technically feasible technique to separate top layer 321 from semiconductor substrate 320 at cleave plane 303 falls within the scope of the invention. Therefore, thickness 304 of top layer 321 can be very precisely controlled and a targeted thickness for interposer 120 can be reliably achieved. Semiconductor substrate 320 can then be polished and re-used to form another interposer.

After interposer 120 is formed by the separation of top layer 321 from semiconductor substrate 320 and through-interposer vias 122 are exposed, a low-temperature dielectric can be deposited on bottom surface 309, e.g., at a temperature less than about 200° C. The dielectric layer can then be patterned, etched, filled, and planarized, using standard techniques, to form a bottom-side pad layer for the attachment of C4 bumps and subsequent mounting of top layer 321 onto a packaging substrate, such as packaging substrate 130 in FIG. 1. Standard flip-chip ball-grid array (FCBGA) assembly processes may be used for attachment to the packaging substrate.

Interposer 120 is formed in method 200 by removing top layer 321 from semiconductor substrate 320 rather than by grinding down a semiconductor substrate to a desired thickness. Thus, when method 200 is used to form interposer 120, the typical inspections that a silicon interposer undergoes after each step of a thinning process may be avoided, thereby simplifying the fabrication process. Inspections that may no longer be necessary when method 200 is used to form a silicon interposer include thickness measurements of the silicon interposer, crack detection, inspection for mechanical damage to the silicon substrate caused by the debonding or thinning processes, inspection for residual bonding adhesive or other foreign matter, etc.

In some embodiments, prior to the material removal process in step 210, a glass or silicon carrier may be bonded to overmolding 140 to facilitate separation of top layer 321 from semiconductor substrate 320. In other embodiments, overmolding 140 can serve as an adequate mechanism by which semiconductor substrate 320 is handled during such separation.

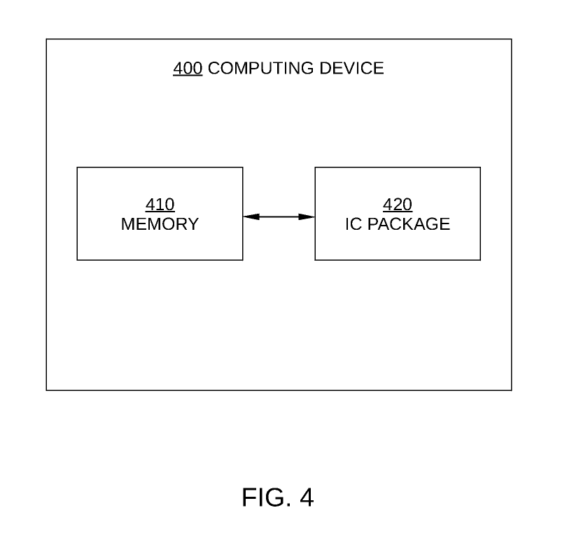

FIG. 4 illustrates a computing device in which one or more embodiments of the present invention can be implemented. Specifically, FIG. 4 is a block diagram of a computing device 400 with an IC package 420 configured according to an embodiment of the present invention. As shown, computer system 400 includes a memory 410 and an IC package 420 that is coupled to memory 410. Computer system 400 may be a desktop computer, a laptop computer, a smartphone, a digital tablet, a personal digital assistant, or other technically feasible computing device. Memory 410 may include volatile, non-volatile, and/or removable memory elements, such as random access memory (RAM), read-only memory (ROM), a magnetic or optical hard disk drive, a flash memory drive, and the like. IC package 420 may be substantially similar in organization and operation to IC package 100, described above in conjunction with FIG. 1, and may include a CPU, a GPU, an application processor or other logic device, a system-on-chip, or any other IC chip-containing device.

In sum, an embodiment of the invention sets forth an IC package that includes an interposer formed from a layer of semiconductor material separated from a substrate and methods of manufacturing the same. Because in such an embodiment the interposer can be formed from a thin layer of semiconductor material that is separated from a substrate and not by a substrate thinning process, vias formed through the interposer can be scaled down significantly in size. Such reduced-size micro vias can be etched and filled much more cost-effectively and result in greatly reduced parasitic capacitance in the integrated circuit package. Moreover, the interposer in such an embodiment can be advantageously fabricated without using imprecise and difficult-to-control thinning operations.

While the foregoing is directed to embodiments of the present invention, other and further embodiments of the invention may be devised without departing from the basic scope thereof, and the scope thereof is determined by the claims that follow.

I claim:

1. An integrated circuit package, comprising:
an interposer formed from a layer of semiconductor material that is separated from a bulk portion of a semiconductor substrate; and
an integrated circuit die coupled to the interposer.

2. The integrated circuit package of claim 1, wherein the interposer includes a plurality of through-silicon vias formed therein.

3. The integrated circuit package of claim 2, wherein the integrated circuit die is electrically coupled to a first through-silicon via included in the plurality of through-silicon vias.

4. The integrated circuit package of claim 2, wherein the integrated circuit die is electrically coupled to the first through-silicon via with an electrically conductive interconnect.

5. The integrated circuit package of claim 4, wherein the electrically conductive interconnect is formed in a non-organic dielectric material.

6. The integrated circuit package of claim 2, further comprising an additional integrated circuit die electrically coupled to a second through-silicon via included in the plurality of through-silicon vias.

7. The integrated circuit package of claim 1, wherein the layer of semiconductor material has a thickness of approximately ten microns or less.

8. A method for forming an integrated circuit package, the method comprising:
implanting ions into a semiconductor substrate to form a weakened interface layer in the semiconductor substrate that is substantially parallel to a surface of the semiconductor substrate;
coupling an integrated circuit die to the surface to form an integrated circuit package; and
separating the integrated circuit package from a bulk portion of the semiconductor substrate at the interface layer.

9. The method of claim 8, further comprising, prior to coupling the integrated circuit die to the surface, forming an aperture in the surface.

10. The method of claim 9, further comprising filling the aperture with an electrically conductive material.

11. The method of claim 10, wherein coupling the integrated circuit die to the surface comprises electrically coupling the integrated circuit die to the electrically conductive material.

12. The method of claim 10, further comprising forming an electrically conductive interconnect on the surface that is configured to electrically couple the integrated circuit die to the electrically conductive material.

13. The method of claim 9, wherein forming the aperture in the silicon surface comprises forming the aperture through the interface layer.

14. The method of claim 8, wherein the ions include hydrogen (H) ions.

15. The method of claim 14, further comprising, prior to separating the integrated circuit package from the bulk portion of the semiconductor substrate, thermally annealing the semiconductor substrate to form hydrogen-silicon bonds in the interface layer.

16. The method of claim 14, further comprising, prior to implanting hydrogen ions into the semiconductor substrate, forming an oxide on the surface.

17. The method of claim 8, further comprising forming an electrically conductive interconnect on the surface.

18. The method of claim 17, further comprising depositing a non-organic dielectric film on the surface, wherein the electrically conductive interconnect is formed within the non-organic dielectric film.

19. The method of claim 8, wherein separating the integrated circuit package the bulk portion of the semiconductor substrate comprises one of a thermal process and a mechanical process.

20. A computing device, comprising:
a memory; and
a microelectronic package coupled to the memory, wherein the microelectronic package comprises:
an interposer formed from a layer of semiconductor material that is separated from a bulk portion of a semiconductor substrate; and
an integrated circuit die coupled to the interposer.
